(19) United States
(12) Patent Application Publication
(10) Pub. No.: US 2007/0077732 A1
(43) Pub. Date: Apr. 5, 2007

(54) Semiconductor device and a manufacturing method of the same

(75) Inventors: Fujio Ito, Tokyo (JP); Hiromichi Suzuki, Tokyo (JP); Masato Numazaki, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/520,666

(22) Filed: Sep. 14, 2006

(30) Foreign Application Priority Data
Sep. 30, 2005 (JP) 2005-286471

(51) Int. Cl. H01L 21/00

(52) U.S. Cl. 438/460; 438/123; 438/110

(57) ABSTRACT

The present invention enhances the processing efficiency of assembling of a semiconductor device. After performing resin molding by a through-gate method, the package dicing is performed such that leads and inclined portions of sealing bodies are cut while adhering a dicing tape to front surfaces of a plurality of sealing bodies. Thereafter, in a state that the plurality of sealing bodies are fixed to the dicing tape, probes are brought into contact with external terminals so as to perform a selection test whereby, after package dicing, it is possible to perform the test in a state that semiconductor devices are held on the dicing tape without accommodating the semiconductor devices in a tray. As a result, it is possible to enhance the processing efficiency of the assembling of a QFN (semiconductor device).

### CROSS-REFERENCE TO RELATED APPLICATION

The present application claims priority from Japanese patent application No 2005-286471 filed on Sep. 30, 2005, the content of which is hereby incorporated by reference into this application.

### BACKGROUND OF THE INVENTION

The present invention relates to a manufacturing method of a semiconductor device, and more particularly to a technique which is effective applicable to a manfacturing method of a semiconductor device which performs through-gate method resin molding.

There has been known a technique in which a substrate has a plurality of mounting portions, a semiconductor chip is fixedly mounted on each mounting portion, the respective semiconductor chips which are fixedly mounted on the respective mounting portions are covered with a common resin layer and, thereafter, the substrate is brought into contact with the resin layer and is adhered to an adhesive sheet, and dicing and measurement are performed in a state that the substrate is adhered to the adhesive sheet thus performing the measurement in a state that semiconductor devices are integrally adhered to the adhesive sheet without being separated into individual semiconductor devices (see patent document 1, for example).

There has been also a technique in which to stretch slackening of a release film, on a lower surface of a floating block, protruding projections are arranged in a grid array to partition respective semiconductor chips which are collectively molded with a resin, and the slackening of the release film is absorbed by increasing a surface area of the molding resin thus preventing the generation of wrinkles around the semiconductor chips which are generated at the time of clamping molds (see patent document 2, for example).

There has been also a technique in which after forming a resin sealed body which seals the semiconductor chips by molding, a peripheral portion of the resin sealed body and a lead frame are cut together along cut lines which are arranged inside lines along outer peripheries of the resin sealed body (see patent document 3, for example).
[Patent Document 1] Japanese Unexamined Patent Publication 2002-26182 (FIG. 6)
[Patent Document 2] Japanese Unexamined Patent Publication 2002-254481 (FIG. 1)
[Patent Document 3] Japanese Unexamined Patent Publication 2004-214233 (FIG. 27)

### SUMMARY OF THE INVENTION

In a resin sealing step of an assembling operation of a semiconductor device such as a QFN (Quad Flat Non-leaded Package), a SON (Small Outline Non-leaded package), as an example of a resin molding method, a MAP (Mold Array Package) method is adopted.

The MAP method performs resin molding by collectively covering a plurality of device regions with one cavity, wherein a sheet having an adhesive layer is preliminarily hermetically adhered to a back surface of a multi-cavity substrate thus performing the molding in a state that resin burrs are not adhered to leads.

That is, in the MAP method, only an outer peripheral portion of the multi-cavity substrate is clamped. Accordingly, due to the influence of warping of the multi-cavity substrate, in a device region close to the center of the substrate which is remote from a clamping portion of a resin forming mold, a gap is liable to be formed between the lead and the sheet, and when a resin enters the gap, a resin burr is formed. Accordingly, to prevent the generation of the resin burrs, the sheet having the adhesive layer is preliminarily adhered to cover the whole back surface of the multi-cavity substrate. As a result, a cost of the sheet is pushed up.

On the other hand, there has been also known a resin molding method which is referred to as a through-gate method besides a MAP method.

In the through-gate method, using a resin forming mold in which a plurality of cavities which are connected with each other through communication gates are formed, the resin molding is performed by covering respective device regions with individual cavities in accordance with one-to-one correspondence. Accordingly, peripheries of the respective sealing bodies are clamped by the mold and hence, a clamping force is increased thus suppressing the formation of resin burrs. Accordingly, it is possible to adopt a sheet having no adhesive layer thus suppressing the increase of a cost of the sheet.

However, when the through-gate method is adopted, a region which constitutes an inclined portion of a side surface of the sealing body and a region of a tie bar which connects a lead are formed and hence, a distance between neighboring sealing bodies is widened. (A distance between the neighboring deice regions becomes wider than the corresponding distance when the MAP method is adopted.) Further, in cutting the sealing body into individual pieces, to prevent clogging (loading) of the blade by making use of a dressing action by simultaneously cutting a resin and the lead, at the time of cutting the sealing body into pieces using the blade, the inclined portion of the side surface of the sealing body is cut. That is, as described in a comparison example shown in FIG. 31, two portions on both sides of the usual dicing region are cut.

Further, a dicing tape 17 which is used at the time of dicing after resin sealing is adhered to a back surface (a surface on which external terminals are arranged) side of the sealing body 31. As described in the comparison example shown in FIG. 32, when the dicing tape 17 is adhered to a front surface side of the sealing body 31 and both sides (two portions) of the dicing region are cut along blades 33 at the time of forming individual pieces in such a state, since the back surface side is set free, a cut remaining portion 32 between both cut portions scatters. Accordingly, to prevent the scattering of the cut remaining portion 32, as described in the comparison example shown in FIG. 31, the sealing body 31 is formed into individual pieces by dicing in a state that the dicing tape 17 is adhered to the back surface side of the sealing body 31 thus adhering the cut remaining portion 32 to the dicing tape 17 to prevent the scattering of the cut remaining portion 32 and, at the same time, in a state that the back surface side is directed downwardly (in a state that the dicing tape 17 is adhered to the back surface side of the sealing body 31).

Further, after dicing, the semiconductor devices which are in an individualized-piece state while being held by the dicing tape 17 to prevent the scattering of individual packages are temporarily accommodated in a tray while maintaining a state that back surface sides of the semiconductor devices are directed downwardly. Thereafter, the individual semiconductor devices are picked up one by one from the tray, each semiconductor device is turned up side down and is set on a handler for selection in a state that the back surface side (external terminal side) of the sealing body 31 is directed upwardly, and the selection is performed. In a selection step which uses the handler, the selection is performed by bringing a probe into contact with a terminal portion 30 on the back surface of the sealing body 31.

Accordingly, after dicing, the semiconductor devices in an individualized-piece state are temporarily accommodated in the tray and, thereafter, the semiconductor devices are respectively transferred to sockets on the handler and are selected and hence, there exists a drawback that an operation up to the setting of the semiconductor devices which are formed into individual pieces in the handler becomes extremely cumbersome.

Further, to prevent the above-mentioned scattering of the cut remaining portion 32, at the time of cutting by dicing, when a blade 33 having a large width is adopted and cutting is performed only one time as described in a comparison example shown in FIG. 33, due to a progress of wear of the blade 33, an after-cut residual portion 34 is formed over an outer peripheral portion of the surface of the sealing body 31 thus giving rise to poor appearance.

Here, in the above-mentioned Patent document 1 (Japanese Unexamined Patent Publication 2002-26182), there is no description with respect to the through-gate method resin molding. Accordingly, before dicing, since there exist no inclined portions on side surfaces of the sealing body between the respective device regions, the above-mentioned problem on the scattering of the cut remaining portion 32 is not taken into consideration. Further, the technique disclosed in the patent document 1 adopts the MAP method and hence, a drawback that the cost of the sheet is pushed up is unavoidable. Further, in the Patent document 2 (Japanese Unexamined Patent Publication 2002-254481), in the same manner as the patent document 1, there is no description with respect to the through-gate method resin molding and, at the same time, the technique disclosed in the pattern document 2 adopts the MAP method and hence, the drawback that the cost of the sheet is pushed up is unavoidable. Further, the patent documents 2 completely fails to describe the probe inspection after dicing and hence, efficient steps up to the setting of the semiconductor devices on the handlers are indefinite. Further, in the Patent document 3 (Japanese Unexamined Patent Publication 2004-214233), there is a description with respect to a technique which cuts the sealing body along cut lines which are arranged inside the lines along the outer periphery of the sealing body using the blade having a large width. In this case, however, as described above, due to a progress of wear on the blade having a large width, the after-cut residual portion is generated on the outer periphery of the surface of the sealing body thus giving rise to poor appearance.

It is an object of the present invention to provide a technique which can enhance a processing efficiency of assembling a semiconductor device.

Further, it is another object of the present invention to provide a technique which can prevent the generation of poor appearance of the semiconductor device.

The above-mentioned and other objects and novel features of the present invention will become apparent from the description of this specification and attached drawings.

To briefly explain the summary of typical inventions among inventions disclosed in this specification, they are as follows.

That is, a manufacturing method of a semiconductor device according to the present invention includes a step which supplies a sealing resin into the inside of a plurality of cavities which are connected with each other through communication gates thus forming a plurality of sealing bodies, a step which cuts portions of leads and the sealing bodies by adhering a dicing tape to surfaces of the plurality of sealing bodies and by allowing blades to intrude into the sealing bodies from back surface sides of the sealing bodies in the dicing-tape adhering state, and a step which performs a test by bringing probes into contact with external terminals formed over back surfaces of the sealing bodies in a state that surfaces of the plurality of sealing bodies are fixed to the dicing tape.

Further, in a manufacturing method of a semiconductor device according to the present invention, semiconductor chips are mounted on respective one ends of a plurality of leads, a plurality of sealing bodies are formed by supplying a sealing resin into the inside of a plurality of cavities which are connected with each other through communication gates, portions of leads and the sealing bodies are cut by adhering a dicing tape to surfaces of the plurality of sealing bodies and by allowing blades to intrude into the sealing bodies from back surface sides of the sealing bodies in the dicing-tape adhering state, and a test is performed by bringing probes into contact with external terminals formed over back surfaces of the sealing bodies in a state that the plurality of sealing bodies are fixed to the dicing tape.

To briefly explain advantageous effects obtained by the typical inventions among the inventions disclosed in this specification, they are as follows.

The plurality of sealing bodies are formed by supplying the sealing resin into the inside of the plurality of cavities which are connected with each other through the communication gates, the portions of leads and the sealing bodies are cut in a state that the dicing tape is adhered to the surfaces of the plurality of sealing bodies and, thereafter, the test (selection) is performed by bringing probes into contact with external terminals in a state that the plurality of sealing bodies are fixed to the dicing tape. Accordingly, after dicing, it is possible to perform the test in a state that the semiconductor devices are held by the dicing tape without being accommodated in a tray. As a result, it is possible to enhance the processing efficiency of the assembling of the semiconductor device.

### BRIEF DESCRIPTION OF THE DRAWINGS

FIG. 1 is a perspective view showing an example of the structure of a semiconductor device of an embodiment 1 of the present invention;

FIG. 2 is a back view showing the structure of the semiconductor device shown in FIG. 1;

FIG. 3 is a cross-sectional view and an enlarged partial cross-sectional view showing the structure of a cross section taken along a line A-A shown in FIG. 1;

FIG. 4 is a cross-sectional view and an enlarged partial cross-sectional view showing the structure of a cross section taken along a line B-B shown in FIG. 1;

FIG. 5 is a flowchart showing an example of assembling steps of the semiconductor device shown in FIG. 1;

FIG. 6 is a cross-sectional view showing an example of the structure up to die bonding which is the assembling step shown in FIG. 5;

FIG. 7 is a cross-sectional view showing an example of the structure up to resin molding which is the assembling step shown in FIG. 5;

FIG. 8 is a cross-sectional view showing an example of the structure up to adhering of dicing tape which is the assembling step shown in FIG. 5;

FIG. 9 is a cross-sectional view showing an example of the structure up to the selecting which is the assembling step shown in FIG. 5;

FIG. 10 is a partial plan view showing an example of the through-gate structure of a forming mold used in the resin molding shown in FIG. 7;

FIG. 11 is a side view showing an example of a region cut by a blade when a sealing body is cut into individual pieces by dicing shown in FIG. 9;

FIG. 12 is a partial cross-sectional view showing an example of a dicing step when a sealing body is cut into individual pieces shown in FIG. 9;

FIG. 13 is a partial cross-sectional view showing an example of a dicing step when a sealing body is cut into individual pieces shown in FIG. 9;

FIG. 14 is a constitutional view showing the structure of a modification when a selection step shown in FIG. 9 is performed;

FIG. 15 is a plan view showing an example of the internal structure of a semiconductor device according to an embodiment 2 of the present invention in a state that the inner structure is viewed through the sealing body in a see-through manner;

FIG. 16 is a cross-sectional view showing the structure of a cross section taken along a line A-A shown in FIG. 15;

FIG. 17 is a plan view showing the structure of the semiconductor device shown in FIG. 15;

FIG. 18 is a back view showing the structure of the semiconductor device shown in FIG. 15;

FIG. 19 is a back view showing the internal structure of a back side of a chip of the semiconductor device shown in FIG. 15;

FIG. 20 is a plan view showing an example of the structure when a dicing tape is adhered in an assembling step of the semiconductor device shown in FIG. 15;

FIG. 21 is a plan view showing an example of the structure after a sealing body is cut into individual pieces in the assembling step of the semiconductor device shown in FIG. 15;

FIG. 22 is a plan view showing an example of the structure when a selection step is performed in the assembling step of the semiconductor device shown in FIG. 15;

FIG. 23 is a partial plan view showing an example of the structure of a portion A shown in FIG. 22;

FIG. 24 is a plan view showing the internal structure of a semiconductor device of a modification of an embodiment 2 of the present invention in a state that the inner structure is viewed through the sealing body in a see-through manner;

FIG. 25 is across-sectional view showing the structure of a cross section taken along a line A-A shown in FIG. 24;

FIG. 26 is a plan view showing the structure of the semiconductor device shown in FIG. 24;

FIG. 27 is a back view showing the structure of the semiconductor device shown in FIG. 24;

FIG. 28 is a back view showing the internal structure of a back side of a chip of the semiconductor device shown in FIG. 24;

FIG. 29 is a partial cross-sectional view showing the structure up to wire bonding which is the assembling step of the semiconductor device of a modification shown in FIG. 24;

FIG. 30 is a partial cross-sectional view showing the structure after resin molding which is the assembling step of the semiconductor device of a modification shown in FIG. 24;

FIG. 31 is a cross-sectional view showing a dicing method used in assembling a semiconductor device of a comparison example;

FIG. 32 is a cross-sectional view showing a dicing method used in assembling a semiconductor device of another comparison example; and

FIG. 33 is a cross-sectional view showing a dicing method used in assembling a semiconductor device of another comparison example.

### DESCRIPTION OF THE PREFERRED EMBODIMENTS

In embodiments described hereinafter, the explanation of parts having the equal or similar constitution is not repeated except for a case in which such repeated explanation is particularly necessary.

Further, in the embodiments described hereinafter, when it is necessary for the convenience sake, the invention is explained by dividing the invention into a plurality of sections or embodiments. However, unless otherwise explicitly described, these sections or embodiments are not irrelevant to each other, wherein there is found the relationship that one section or embodiment is a modification, a detail, a complementary explanation of a portion or the whole of other section or embodiment.

Further, in the embodiments described hereinafter, when the number of elements and the like (including pieces, numerical values, quantity, range and the like) are referred to, unless otherwise particularly specified or the number is apparently limited to a specified number in principle, the number is not limited to the specified number and may be set to a value which is larger or lower than the specified number.

Hereinafter, embodiments of the present invention are explained in detail in conjunction with drawings. Here, in all drawings for explaining the embodiments, members having identical functions are given same symbols and their repeated explanation is omitted.

### Embodiment 1

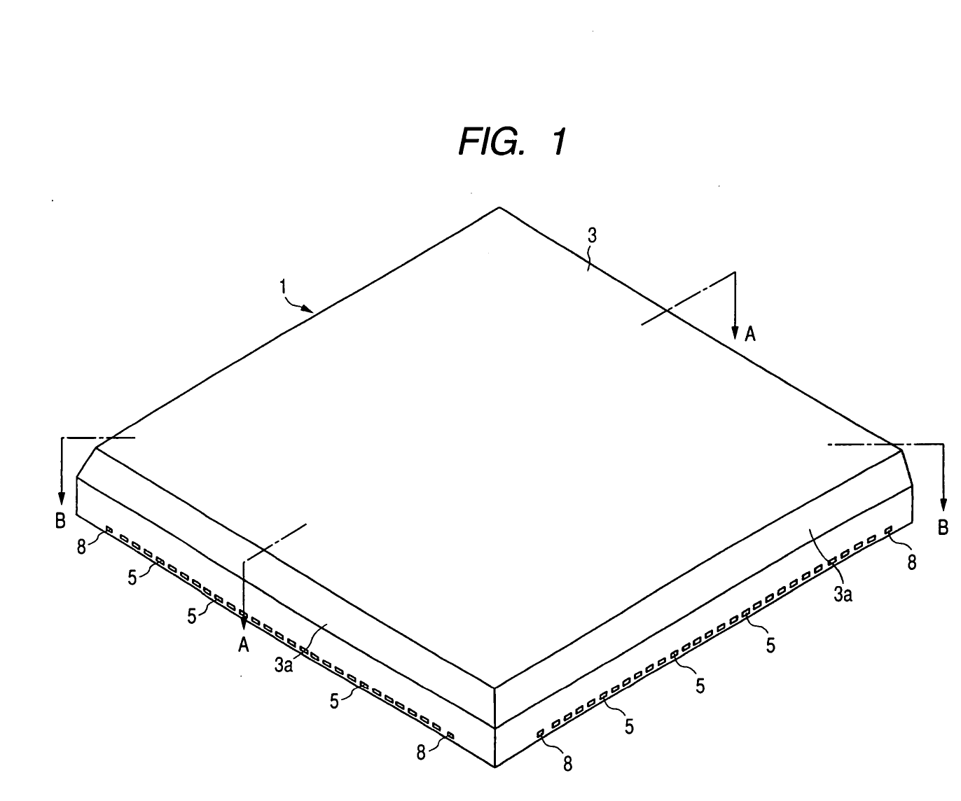

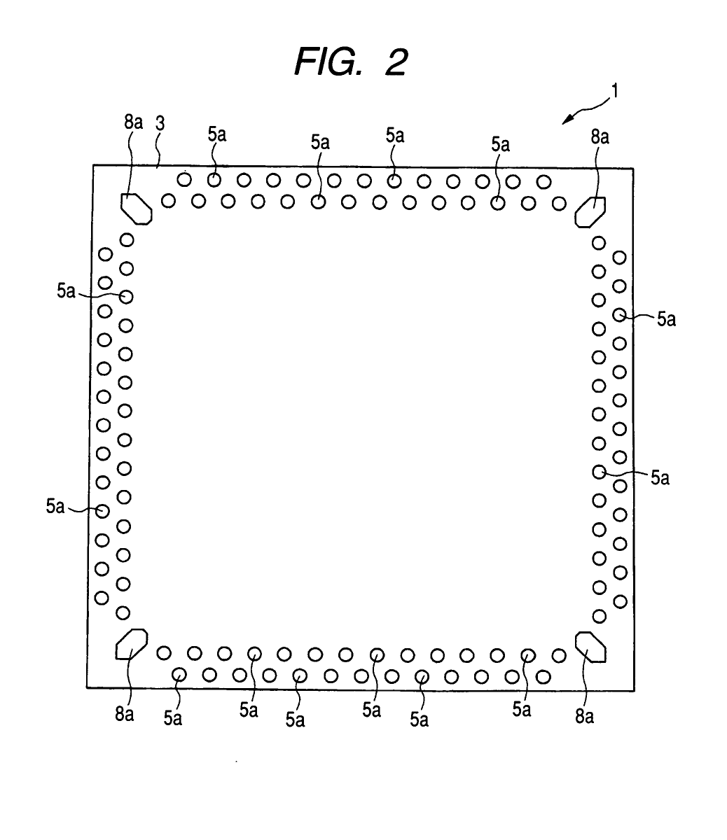

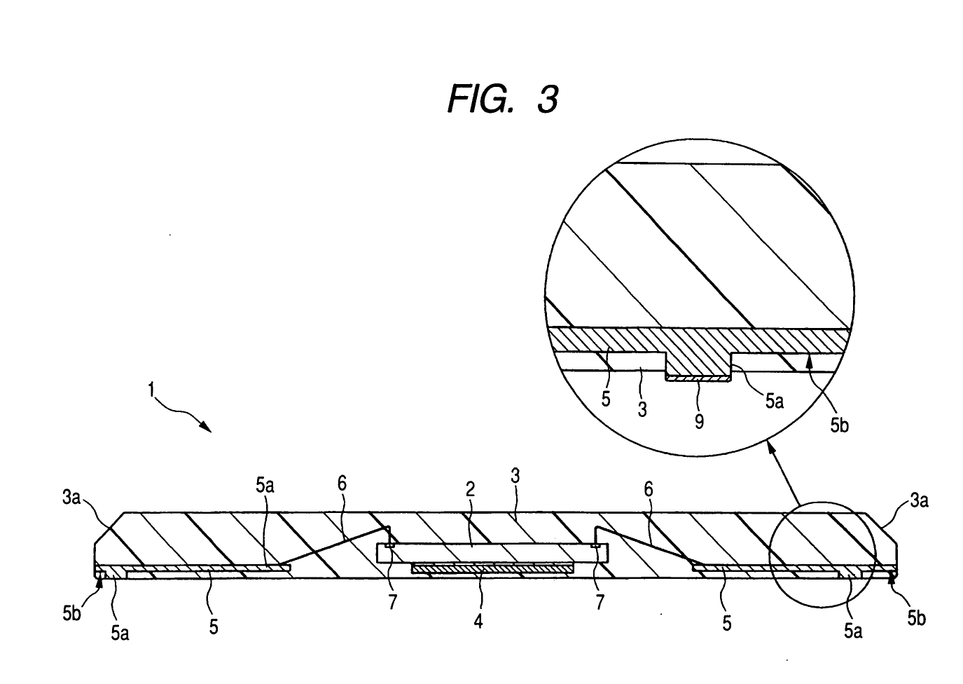

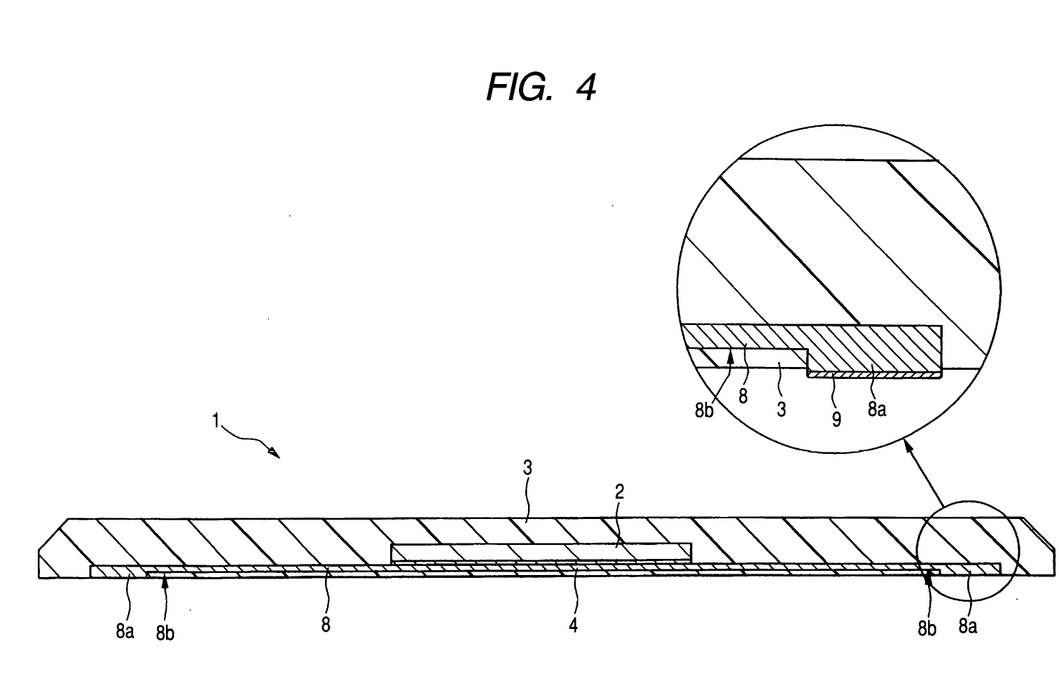

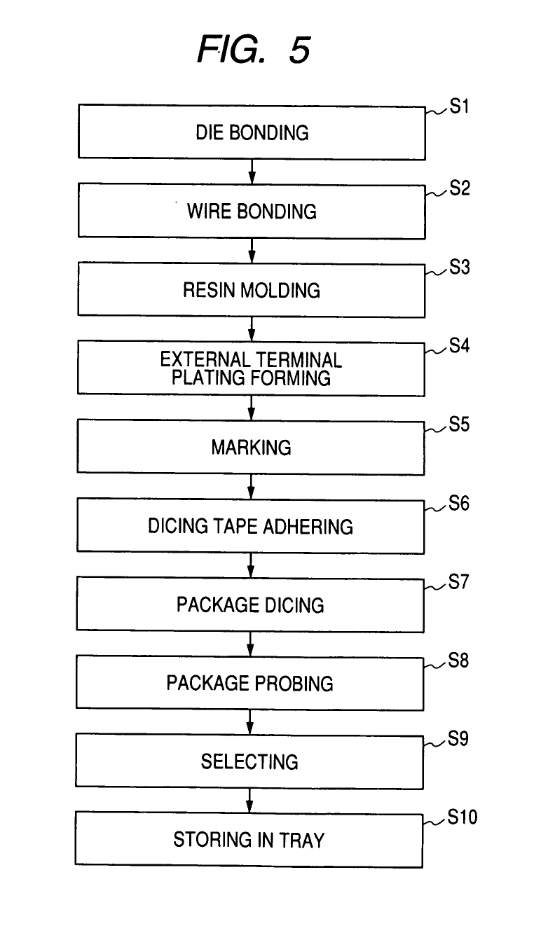

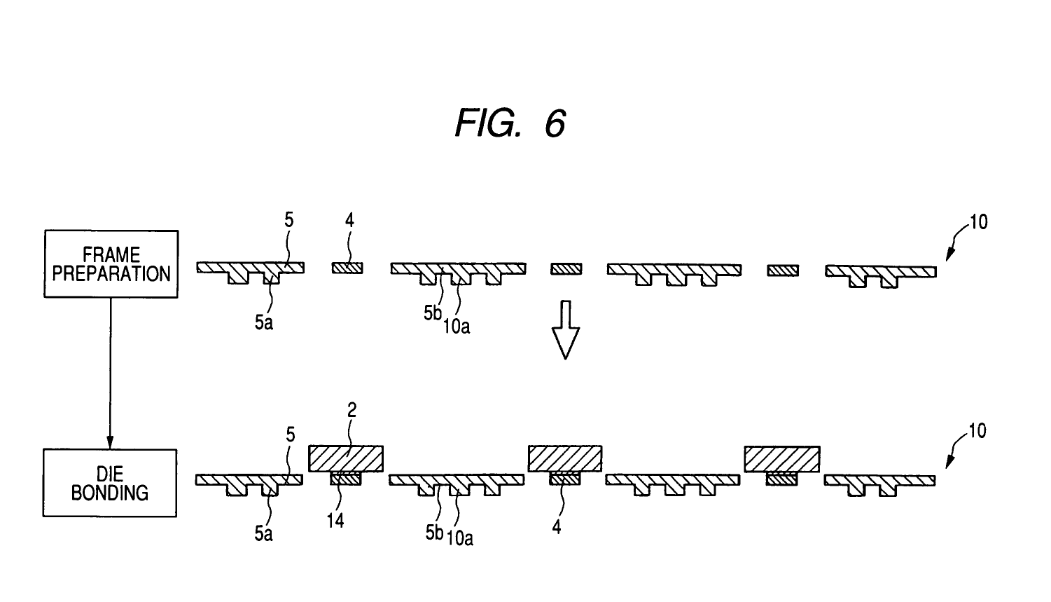

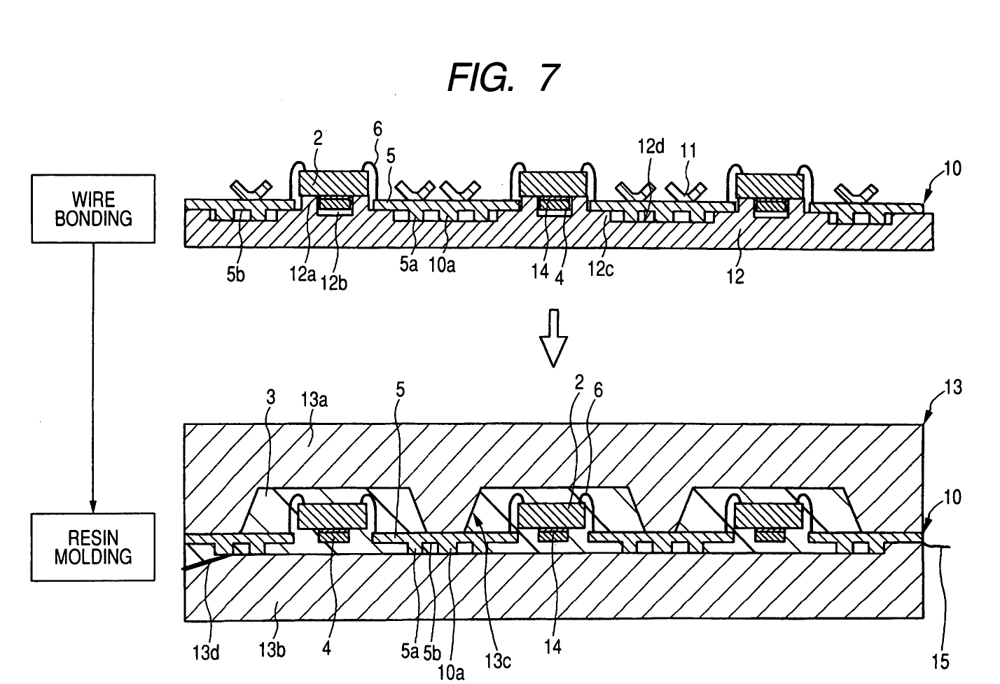

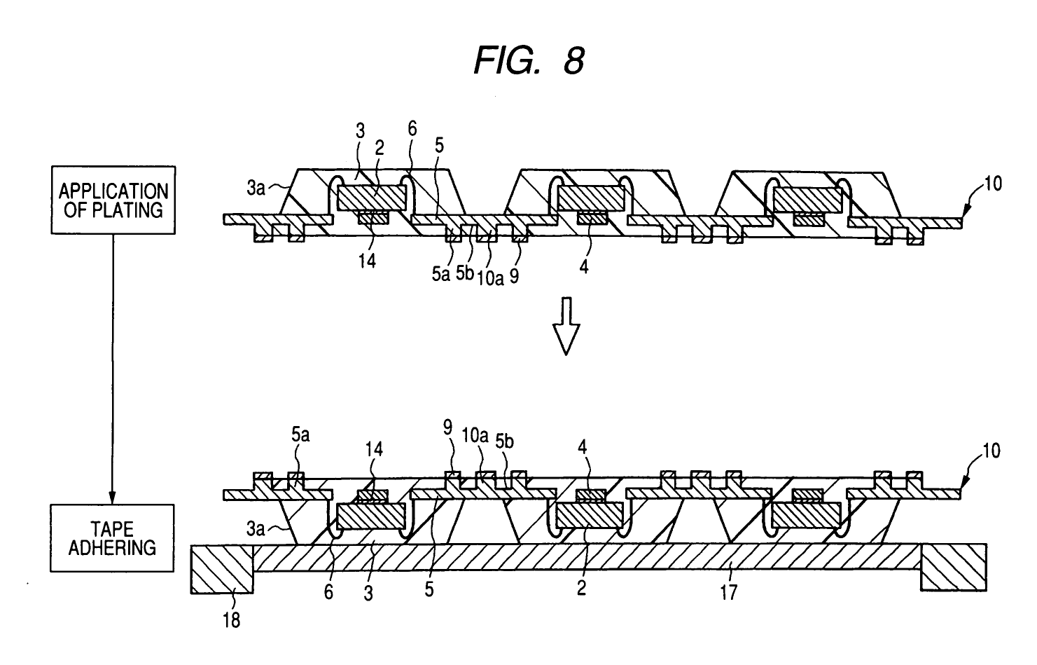

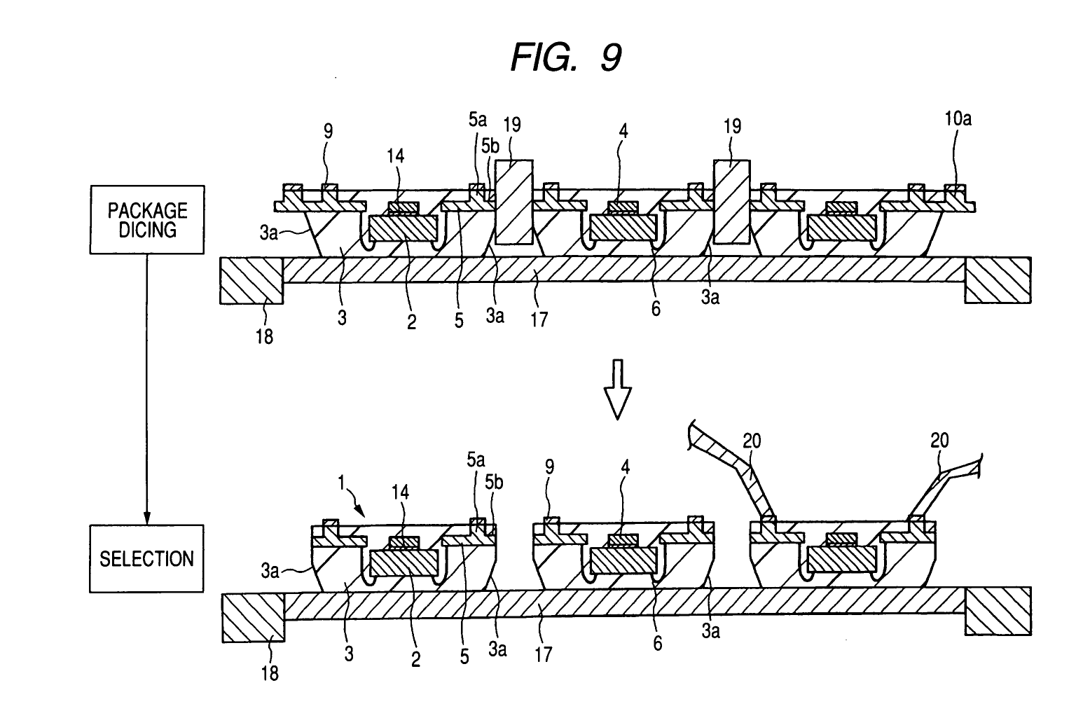

FIG. 1 is a perspective view showing an example of the structure of a semiconductor device of an embodiment 1 of the present invention, FIG. 2 is a back view showing the structure of the semiconductor device shown in FIG. 1, FIG. 3 is a cross-sectional view and an enlarged partial cross-sectional view showing the structure of across section taken along a line A-A shown in FIG. 1, FIG. 4 is a cross-sectional view and an enlarged partial cross-sectional view showing the structure of a cross section taken along a line B-B shown in FIG. 1. Further, FIG. 5 is a flow chart showing an example of assembling steps of the semiconductor device shown in FIG. 1, FIG. 6 is a cross-sectional view showing an example of the structure up to die bonding which is the assembling step shown in FIG. 5, FIG. 7 is a cross-sectional view showing an example of the structure up to resin molding which is the assembling step shown in FIG. 5, FIG. 8 is a cross-sectional view showing an example of the structure up to adhering of dicing tape which is the assembling step shown in FIG. 5, and FIG. 9 is across-sectional view showing an example of the structure up to a selecting step which is the assembling step shown in FIG. 5.

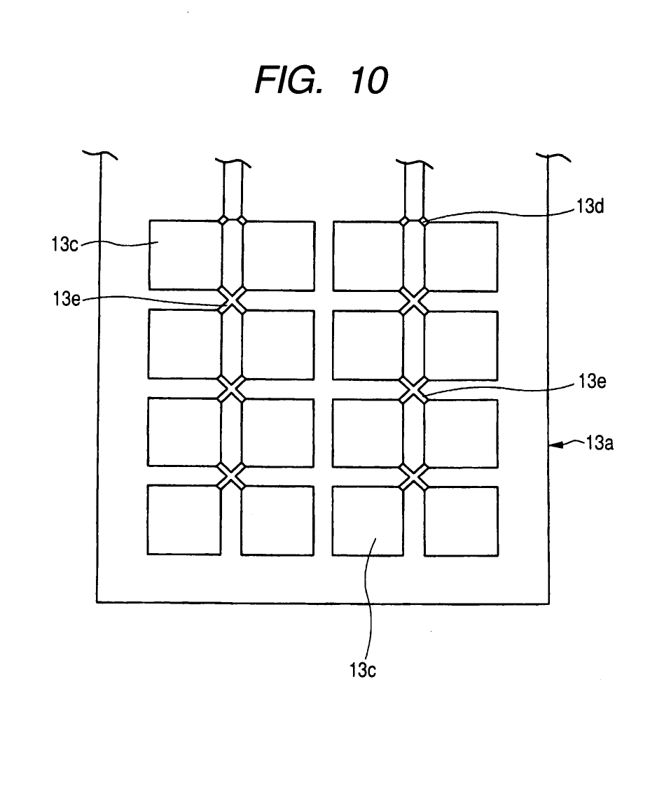

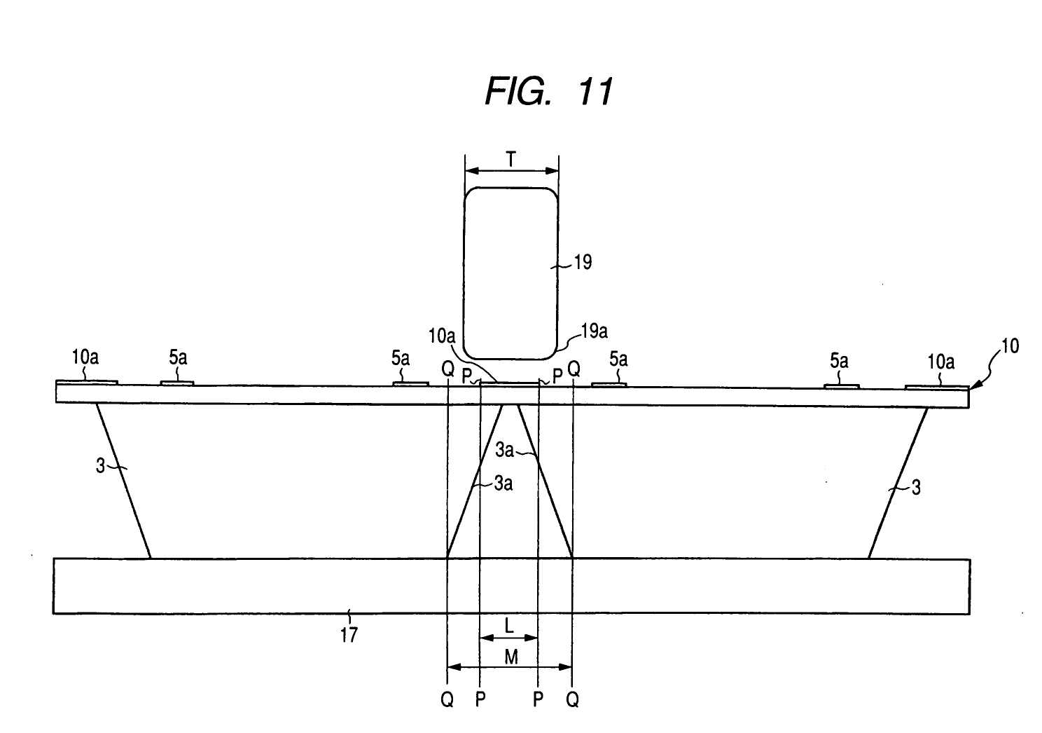

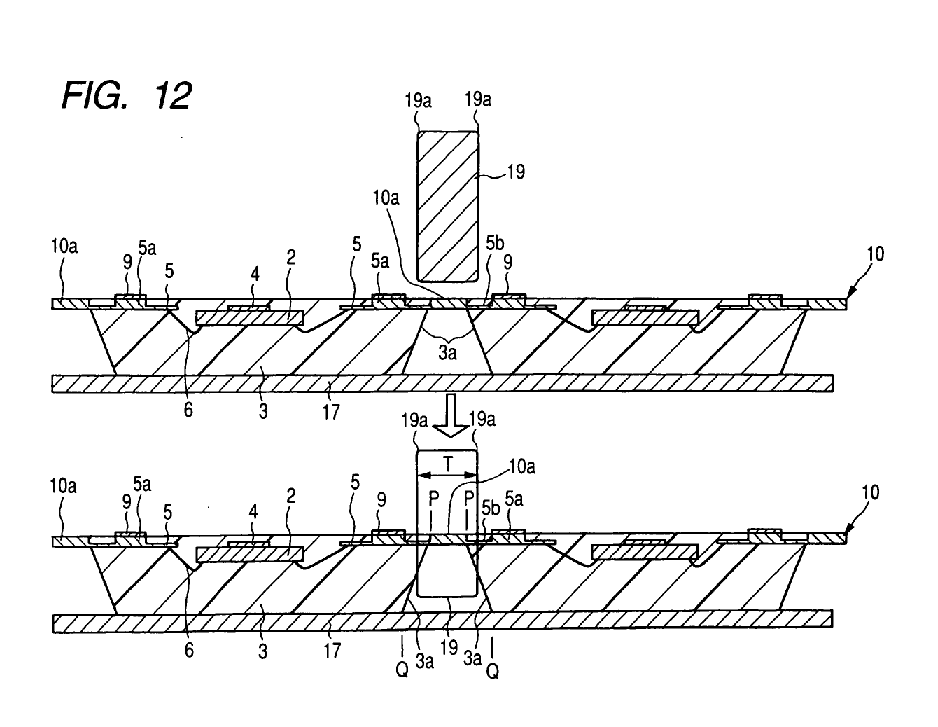

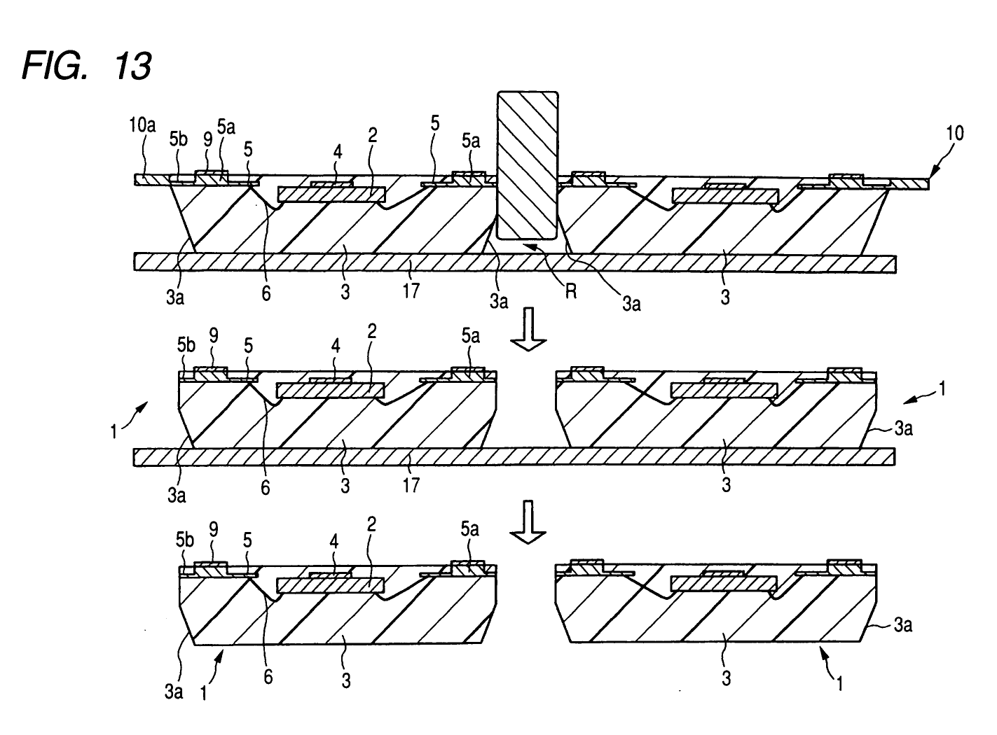

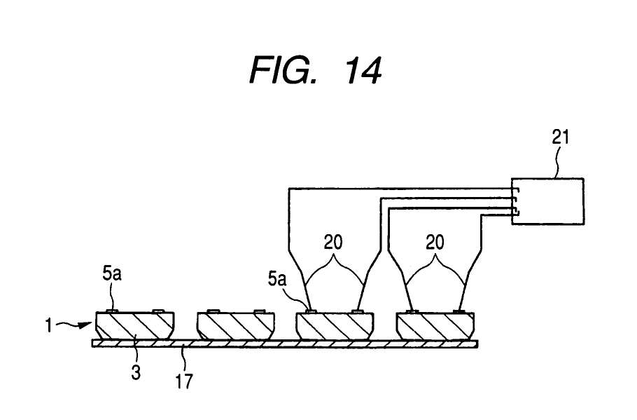

Further, FIG. 10 is a partial plan view showing an example of the through-gate structure of a forming mold used in the resin molding shown in FIG. 7, FIG. 11 is a side view showing an example of a region cut by a blade when a sealing body is cut into individual pieces by dicing shown in FIG. 9, FIG. 12 and FIG. 13 are respectively partial cross-sectional views showing examples of dicing steps when sealing bodies are cut into individual pieces shown in FIG. 9, and FIG. 14 is a constitutional view showing the structure of a modification when a selection step shown in FIG. 9 is performed.

A semiconductor device according to the embodiment 1 shown in FIG. 1 to FIG. 4 is a miniaturized resin-sealed-type and surface-mounting-type semiconductor package and, as shown in FIG. 2, is of a non lead type which arranges a plurality of external terminals (first portion) 5a in an exposed manner in a peripheral portion of a back surface of a sealing body 3. In this embodiment 1, QFN1 is explained as an example of the above-mentioned semiconductor device.

A semiconductor chip 2 which is assembled in the QFN1 is arranged in the center portion of the sealing body 3 in a state that the QFN1 is mounted on the upper surface of a tab 4 which forms a chip mounting portion made of metal. The tab 4 is, to enable to mount the semiconductor chips 2 having plural kinds of sizes, constituted in a so-called small tab structure in which a diameter thereof is smaller than a diameter of the semiconductor chip 2.

As shown in FIG. 4, the tab 4 is supported by four suspension leads 8 which are integrally formed with the tab 4 and extend in the corner portion directions of the sealing body 3.

As shown in FIG. 3, around the tab 4 on which the semiconductor chip 2 is mounted, a plurality of (for example, 116) leads 5 is arranged at a substantially equal interval. These leads 5 have respective one end portion sides (side close to the semiconductor chip 2) thereof electrically connected with a bonding pad 7 on a main surface of the semiconductor chip 2 by way of Au wires 6 which form conductive wires, and another end portion sides are terminated on side surfaces of the sealing body 3.

Each lead 5 has, to decrease a distance between the lead 5 and the semiconductor chip 2, one end portion side thereof (side close to the semiconductor chip 2) pulled around to the vicinity of the tab 4. The lead 5 is made of the same metal as the tab 4 and the suspension lead 8 and has a thickness of approximately 65 μm to 75 μm, for example.

Further, each lead 5 has, as shown in a enlarged view in FIG. 3, an external terminal 5a which forms a first portion exposed in the back surface of the sealing body 3 and a thin wall portion 5b which forms a second portion formed to have a thickness smaller than the external terminal 5a using a half etching process, and the thin portion 5b is embedded in the inside of the sealing body 3 and the whole periphery thereof is covered with a resin.

As shown in FIG. 1, on side surfaces of the sealing body 3, another end portions of the leads 5 and distal end portions of the suspension leads 8 are exposed. Another end portions of the leads 5 and distal end portions of the suspension leads 8 which are exposed on the side surfaces of the sealing body 3 have respective whole peripheries (upper surfaces, lower surfaces and both side surfaces) thereof covered with a resin which constitutes the sealing body 3. Further, as shown in FIG. 1 and FIG. 3, inclined portions 3a are formed over the whole peripheries of the side surfaces of the sealing body 3.

Here, as will be explained later, the QFN1 of this embodiment is manufactured such that the semiconductor chip 2, the tab 4, the leads 5 and the suspension leads 8 are molded with resin thus forming the sealing body 3 and, thereafter, the leads 5 and the suspension leads 8 which are exposed to the outside of the sealing body 3 are cut by a dicer. Here, in cutting the leads 5 and the suspension leads 8 by the dicer, by cutting the leads 5 and the suspension leads 8 at regions of the thin-wall portions 5b which are covered with the resin, the cutting is performed such that the respective whole peripheries of another end portions of the leads 5 and the distal end portions of the suspension leads 8 are covered with the resin and hence, it is possible to prevent a defect that metal burrs are generated on respective cut surfaces of the leads 5 and the suspension leads 8.

That is, by cutting the thin-wall portions 5b of the leads 5 in a resin wrapped state, it is possible to prevent clogging of a blade (see FIG. 9) 19 for dicing by a dressing action. As a result, it is possible to prevent a defect that metal burrs are generated on the cut surfaces of the respective leads 5.

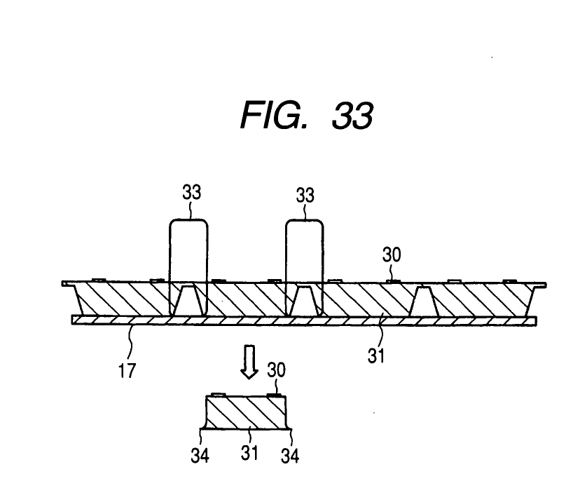

Further, as will be explained later, by cutting, with the dicer, the leads 5 and the suspension leads 8 at regions of the inclined portions 3a outside an outer peripheral portion of a front surface of the sealing body 3, even when the wear of the blade 19 progresses, it is possible to cut the leads 5 and the suspension leads 8 without generating the after-cut residual portions 34 described in the comparison example shown in FIG. 33, thus preventing the occurrence of poor appearance of the QFN1.

Here, since the cutting is performed in the regions of the inclined portions 3a outside the outer peripheral portions of the front surface of the sealing body 3, the inclined portions 3a are formed over the whole surface of the side surfaces of the sealing body 3.

Further, as shown in FIG. 2, the back surface (substrate mounting surface) of the sealing body 3 is formed in a quadrangular shape, and external terminals 5a which constitute portions of the plurality of leads 5 are exposed along respective four sides of a peripheral portion of the back surface. For example, 116 pieces of external terminals 5a are arranged in two rows in a staggered manner along the respective sides of the sealing body 3, wherein front surfaces of the external terminals 5a project to the outside from the back surface of the sealing body 3. Although these external terminals 5a are integrally formed with the leads 5, a thickness of the external terminals 5a is made approximately twice (approximately 125 μm to 150 μm) as large as a thickness of thin-wall portions 5b of the leads 5.

Further, on the back surface of the sealing body 3, four projections 8a are formed. These projections 8a are arranged in the vicinity of corner portions of the sealing body 3, and the projections have front surfaces thereof projected outwardly from the back surface of the sealing body 3. These projections 8a are, as shown in FIG. 4 which is an enlarged view, integrally formed with the suspension leads 8 and a thickness thereof is made approximately twice (approximately 125 μm to 150 μm) as large as a thickness of the thin-wall portions 8b of the suspension leads 8, that is, is made equal to the thickness of the external terminals 5a.

Further, to respective front surfaces of the external terminals 5a and the projections 8a which project to the outside of the sealing body 3, a solder layer 9 is applied by plating, printing or the like. The QFN1 is mounted by electrically connecting the front surfaces of the external terminals 5a with electrodes (foot prints) of a printed wiring board by way of the solder layer 9. Here, by joining the front surfaces of the projections 8a to the printed wiring board via the soldering layers 9, is possible to enhance the reliability of connection between the QFN1 and the printed wiring board.

Next, the assembling of the QFN1 of this embodiment 1 is explained in conjunction with a flow chart shown in FIG. 5 to FIG. 9.

First of all, as shown in FIG. 6, a lead frame 10 which includes the tabs 4 which constitute the chip mounting portions and the plurality of leads 5 which are arranged around the tabs 4 is prepared. Here, each lead 5 has the external terminals 5a and the thin-wall portion 5b which is thinner than the external terminals 5a. The thin-wall portion 5b is formed by half etching and hence, the thickness of the external terminals 5a is approximately twice as large as the thickness of the thin-wall portion 5b.

Thereafter, die bonding in step S1 shown in FIG. 5 is performed. Here, as shown in FIG. 6, the semiconductor chip 2 is mounted on the tab 4 by way of an Ag paste 14.

Thereafter, wire bonding in step S2 is performed. That is, bonding pads 7 (see FIG. 3) of the semiconductor chip 2 and the corresponding leads 5 are electrically connected with each other using Au wires 6 which constitute conductive wires.

Here, as shown in FIG. 7, first of all, the semiconductor chip 2 is arranged above a projecting chip mounting portion 12a of a heat block 12 such that the tab 4 is arranged in a recessed portion 12b formed in the inside of a projecting chip supporting portion 12a, and the lead frame 10 is arranged above the heat block 12 such that the leads 5 are arranged above the lead receiving portions 12d formed in an outer periphery of the chip supporting portion 12a. Further, at the time of performing the wire bonding, the wire bonding is performed by pushing the leads 5 to the lead receiving portion 12d of the heat block 12 from above the lead 5 using a lead pusher 11 and hence, a projecting stepped portion 12c of the lead receiving portion 12d supports thinly formed portion of an end portion of the lead 5 by half etching whereby the stepped portion 12c surely receives a load at the time of wire bonding.

In this manner, by performing the wire bonding by surely bringing the lead receiving portion 12d of the heat block 12 and the lead 5 into contact with each other, it is possible to perform the wire bonding in a state that heat from the heat block 12 is sufficiently transmitted to the lead 5 and hence, the wire connection strength can be enhanced.

Here, the projecting stepped portion 12c of the lead receiving portion 12d of the heat block 12 may not be always provided, and the heat block 12 having the lead receiving portion 12d which is formed of only a flat surface may be used. In this case, it is preferable that an end portion (a second bonding portion) of an Au wire 6 which is connected to the lead 5 in the wire bonding step is fixed to a region where the external terminal 5a which constitutes a projecting portion of the lead 5 is formed. This is because that even when the lead receiving portion 12d of the heat block 12 is formed of only the flat surface, the external terminal 5a to which half etching is not provided can come into contact with the heat block 12, that is, the heat from the heat block 12 is easily transferred to the external terminals 5a.

That is, in the wire bonding step, by performing the wire bonding in a state that the lead frame 10 is arranged on the heat block 12 and the lead frame 10 is heated, it is possible to increase the wire connection strength. The lead 5 of the QFN1 of this embodiment suppresses the lowering of cutting property in the succeeding cutting step and hence, the lead 5 is formed of the thin-wall portion 5b by half etching except for the region of the external terminal 5a. Accordingly, by connecting the end portion (second bonding portion) of the Au wire 6 to the region where the external terminal 5a of the lead 5 is formed, the heat of the heat block 12 is transferred to the wire connecting portion (second bonding portion) thus enhancing the wire connecting strength.

Here, even when the projecting stepped portion 12c is not formed over the lead receiving portion 12d of the heat block 12, the end portion (second bonding portion) of the Au wire 6 may be connected to the thin-wall portion 5b of the lead 5 which is formed by half etching. Also in this case, it is possible to transfer the heat of the heat block 12 to the second bonding portion of the lead 5.

After completion of the wire bonding, the resin molding described in step S3 shown in FIG. 5 is performed. In the molding step of the QFN1 of this embodiment 1, the resin molding is performed using an upper mold 13 of a through-gate method shown in FIG. 10.

In the through-gate method, as shown in FIG. 7, using an upper mold 13a in which a plurality of cavities which is connected with each other by way of through gates (communication gates) is formed in a grid array, the resin molding is performed by covering the respective device regions with the individual cavities 13c in a one-to-one correspondence.

Here, first of all, in a state that a sheet 15 is arranged on a lower mold 13b, the lead frame 10 is sandwiched between the upper mold 13a and the lower mold 13b of the resin forming mold 13 and, thereafter, a sealing resin is supplied into the plurality of cavities 13c which are formed between the upper mold 13a and the lower mold 13b and are connected with each other from the gate 13d by way of the through gates 13e thus integrally forming a plurality of sealing bodies 3.

In the through-gate method, at the time of injecting resin, portions right close to the peripheries of the cavities 13c are clamped between the upper mold 13a and the lower mold 13b and hence, the clamping force can be increased whereby the formation of the resin burrs can be suppressed. Further, it is possible to adopt the sheet 15 having no adhesive layer and hence, the increase of the cost of the sheet 15 can be suppressed.

Accordingly, as shown in FIG. 7, it is possible to seal the semiconductor 2, the Au wire 6 and the thin-wall portion 5b of the lead 5b in the inside of the sealing body 3.

Here, when the through-gate method is adopted, between the neighboring sealing bodies, as shown in FIG. 8, a region of the inclined portion 3a of the side surface of the sealing body 3 and the region of a tie bar 10a which connects the leads 5 are formed and hence, a wide distance between the neighboring sealing bodies 3 is formed.

After completion of resin molding, the plating is formed over the external terminals described in step S4 shown in FIG. 5. In applying the plating as shown in FIG. 8, solder plating is applied to respective external terminals 5a of the leads 5 which are exposed on the back surface of the sealing body 3 thus forming solder layers 9.

Thereafter, marking in step S5 is performed thus attaching marks such as production numbers on a surface of the sealing body 3.

Thereafter, adhering of dicing tape described in step S6 is performed. In adhering the dicing tape as shown in FIG. 8, the front surface and the back surface of the sealing body 3 are turned up side down, and the dicing tape 17 which is held by a tape fixing jig 18 is adhered to the surface side of the sealing body 3 in a state that the back surface of the sealing body 3 is directed upwardly.

Thereafter, package dicing described in step S7 is performed. In performing the package dicing in FIG. 9, in a state that the dicing tape 17 is adhered to the surfaces of the plurality of sealing bodies 3, dicing blades 19 for dicing are allowed to intrude the sealing bodies 3 from the back surface side (upward) of the sealing bodies 3 thus collectively cutting portions of the leads 5 and the sealing bodies 3 of the lead frame 10.

In the package dicing, as shown in FIG. 11 and FIG. 12, it is desirable to cut the package at the inclined surface 3a of the side surface of the sealing body 3 and the thin-wall portion 5b (second portion embedded in the inside of the sealing body 3) which is formed by half etching of the lead 5 by one dicing. That is, by cutting the package by one dicing (one portion) using the blade 19 having a large width, an cut remaining portion 32 which is generated by cutting the package twice (two portions) as shown in a comparison example in FIG. 32 is no more formed thus preventing the generation of the cut remaining portion 32.

Further, by cutting the package at a position outside the outer peripheral portion of the front surface of the sealing body 3 and at the inclined portion 3b of the side surface, even when the wear of the blade 19 progresses, it is possible to prevent the generation of after-cut residual portions 34 (resin burrs) of the resin at an end portion of the surface of the sealing body 3 described in the comparison example shown in FIG. 33.

Further, by cutting the package at the thin-wall portions 5b (second portions which are embedded in the inside of the sealing body 3) of the leads 5 which are formed by half etching, it is possible to cut the resin and the leads 5 collectively and hence, the clogging of blades 19 can be prevented by a dressing action. That is, the thin-wall portion 5b of the lead 5 has the whole periphery thereof covered with the resin and hence, by cutting the metal wrapped by the resin, the generation of metal burrs can be prevented thus preventing the closing of the blades 19. When the mere cutting is performed at the thin-wall portions 5b of the leads 5, it may be possible to suppress the clogging of the blades 19. However, as described in the comparison example shown in FIG. 33, since the wear of the blade 33 progresses, the after-cut residual portion 34 is formed over the outer peripheral portion of the surface of the sealing body 31.

In this manner, to cut the inclined portions 3a of the side surfaces of the sealing body 3 and the thin-wall portions 5b of the leads 5 by one dicing, the blade 19 having a large width is used. Here, it is a requisite that the thickness (T) of the blade 19 is set such that the edge portions 19a are arranged at the inclined portion 3a of the side surface of the sealing body 3 and the thin-wall portion 5b of the leads 5 which constitute the second portion at the time of cutting.

That is, using the blade 19 having the thickness (T) which has the edge portions 19a thereof arranged in the region of the thin-wall portion 5b of the lead 5 and the region between an end portion (P) of the tie bar 10a and an outer peripheral portion (Q) of the surface of the sealing body 3, the cutting is performed at a position within such a range. As shown in FIG. 11, for example, assuming a distance between end portions of the tie bar 10a (distance between P-P) as L and a distance between the outer peripheral portions of the front surfaces of the sealing bodies 3 of the neighboring QFN (distance between Q-Q) as M, the thickness (T) of the blade 19 has the relationship L<T<M.

Accordingly, it is possible to prevent the generation of the cut remaining portions 32, the formation of the after-cut residual portions 34 and the clogging of the blades 19.

For example, the cutting is performed using the blade 19 having a large thickness (T) of 1 mm.

Further, at the time of cutting, as indicated by an R portion shown in FIG. 13, it is preferable to perform the cutting in a state that blade 19 is spaced apart from the dicing tape 17. Due to such a constitution, water supplied to the blade 19 at the time of cutting easily enters a gap (R portion) between the dicing tape 17 and the neighboring sealing bodies 3 and hence, resin dusts which enter the gap are removed thus preventing the lowering of the cutting efficiency. Further, it is possible to lower a friction heat of the blade 19 thus preventing the clogging of the blade 19.

After completion of the package dicing, the package probing described in step S8 in FIG. 5 is performed and, thereafter, the selection which is described in step S9 is performed. Here, as indicated in the selection in FIG. 9, a state in which a plurality of cut sealing body 3 is fixed to the dicing tape 17 is maintained and, in such a state, a probe 20 is brought into contact with the external terminal 5a which is arranged on the back surface of the sealing body 3 directed upwardly thus performing the selection test.

That is, the test is performed by bringing the probe 20 into contact with the external terminal 5a thus selecting the QFN 1 having good quality.

Here, as indicated in the modification shown in FIG. 14, using a tester 21 on which a plurality of probes 20 is mounted, it is also possible to perform, in the selection processing, the test on a plurality of QFN 1 simultaneously by bringing the probes 20 into contact with the external terminals 5a of the plurality of QFN 1 on the dicing tape 17.

After completion of the selection, the tray accommodation indicated in step S10 shown in FIG. 5 is performed. Here, the QFN 1 which is determined as the product having good quality in the selection processing is accommodated in the tray. The assembling of the QFN 1 is completed with such accommodating.

According to the manufacturing method of the semiconductor device of the embodiment 1, after performing the resin molding by the through-gate method, the package dicing is performed in a state that the dicing tape 17 is adhered to the surface of the plurality of the sealing body 3 and, thereafter, the selecting test is performed in a state that the plurality of sealing body 3 is fixed to the dicing tape 17. Accordingly, after the package dicing, the test can be performed while holding the sealing body 3 by the dicing tape 17 without accommodating the sealing body 3 into the tray.

That is, the plurality of sealing bodies 3 are formed by supplying the sealing resin into the inside of the plurality of cavities 13c which are connected with each other by way of the through gate 13e, the lead 5 and the inclined portion 3a of the sealing bodies 3 are cut in a state that the dicing tape 17 is adhered to the surface of the plurality of sealing bodies 3 and, thereafter, the selection test is performed by bringing probes 20 into contact with external terminals 5a in a state that the plurality of sealing bodies 3 are fixed to the dicing tape 17. Accordingly, after the package dicing, it is possible to perform the selection test in a state that the semiconductor devices are held by the dicing tape 17 without being accommodated in the tray.

As a result, it is possible to enhance the processing efficiency in assembling the QFN 1.

Further, in forming individual pieces by dicing the sealing body 3, in the inclined portions 3a of the side surfaces of the plurality of the respective sealing bodies 3, by cutting the thin wall portion 5b of the lead 5 and the inclined portion 3a of the sealing body 3 using the blade 19, the cutting is performed in a region of the inclined portion 3a of the outside of the outer peripheral portion of the surface of the sealing body 3 and hence, even when wear of the blade 19 progresses, it is possible to cut without generating the after-cut residual portion 34 on the outer peripheral portion of the front surface of the sealing body 3.

Accordingly, there is no possibility that the package dicing causes the poor appearance thus preventing the QFN1 from exhibiting the poor appearance.

### Embodiment 2

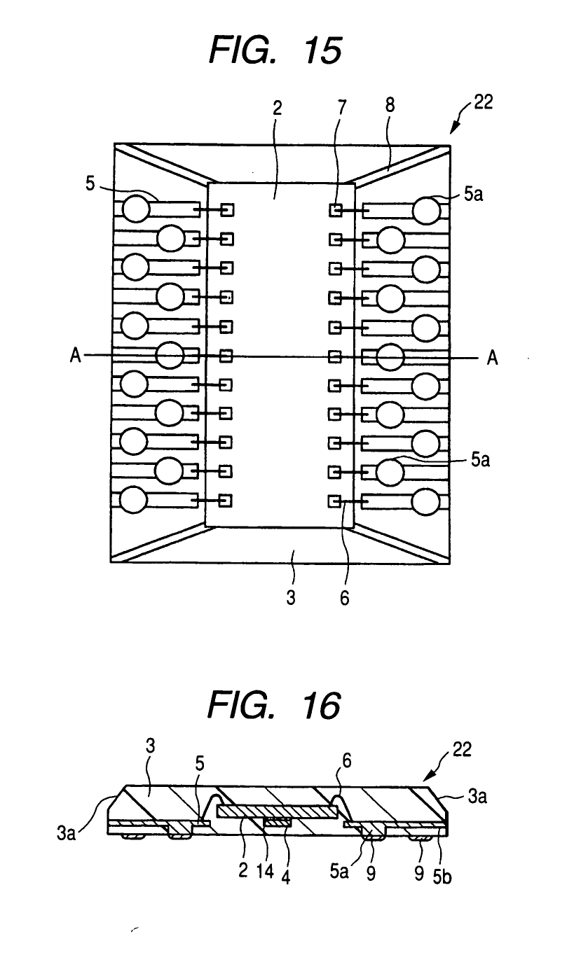

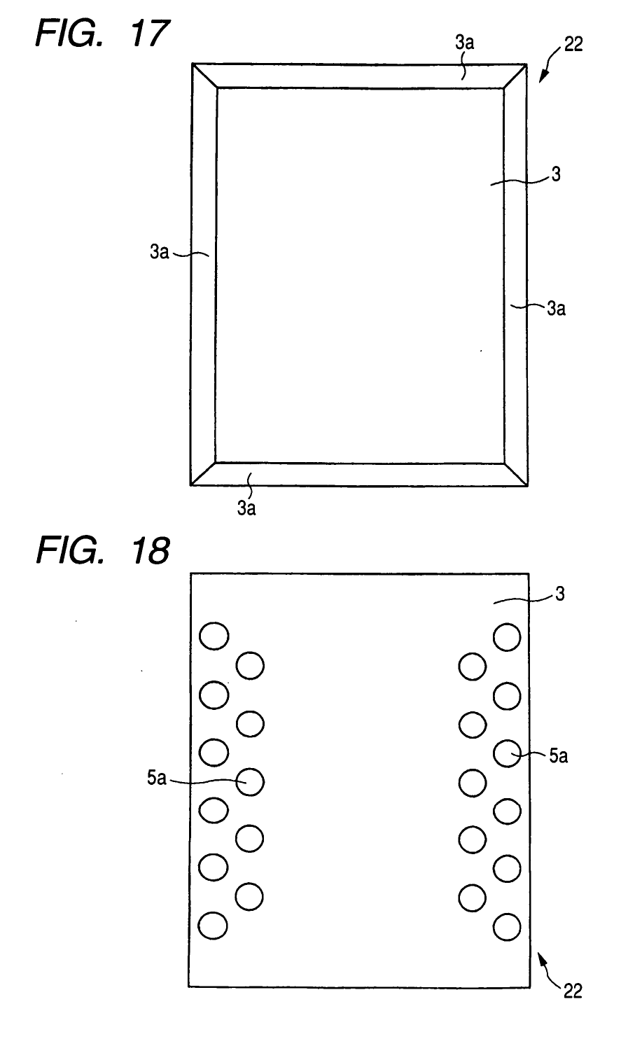

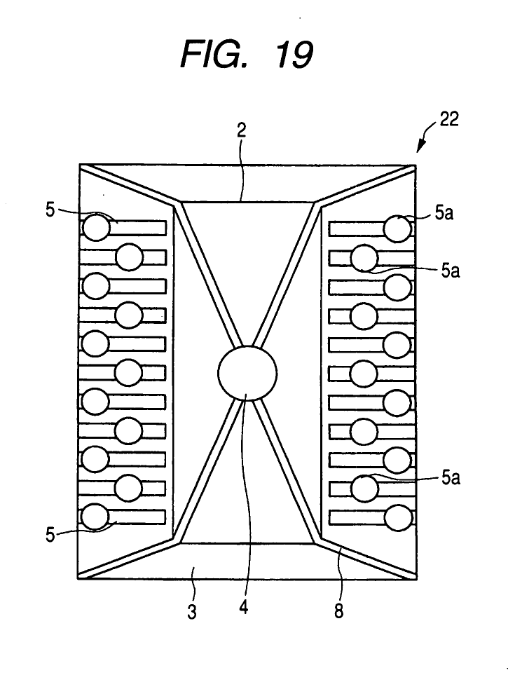

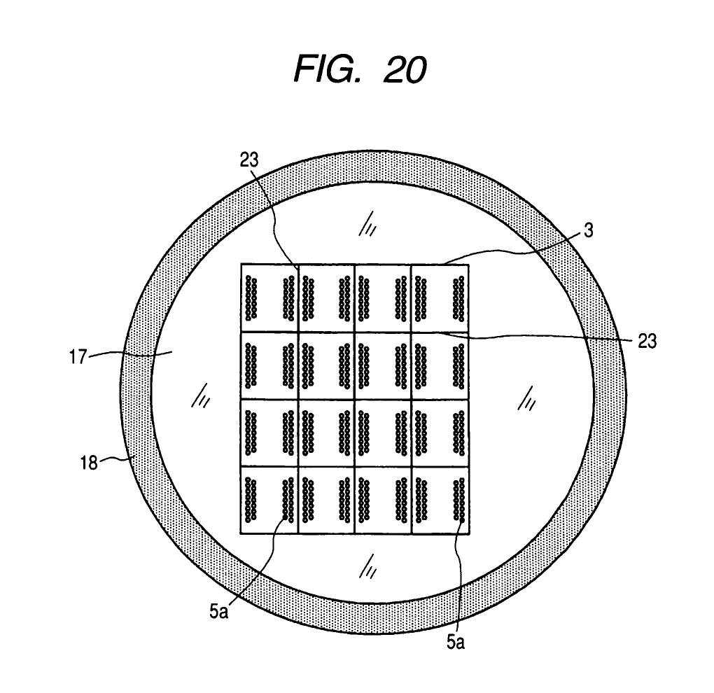

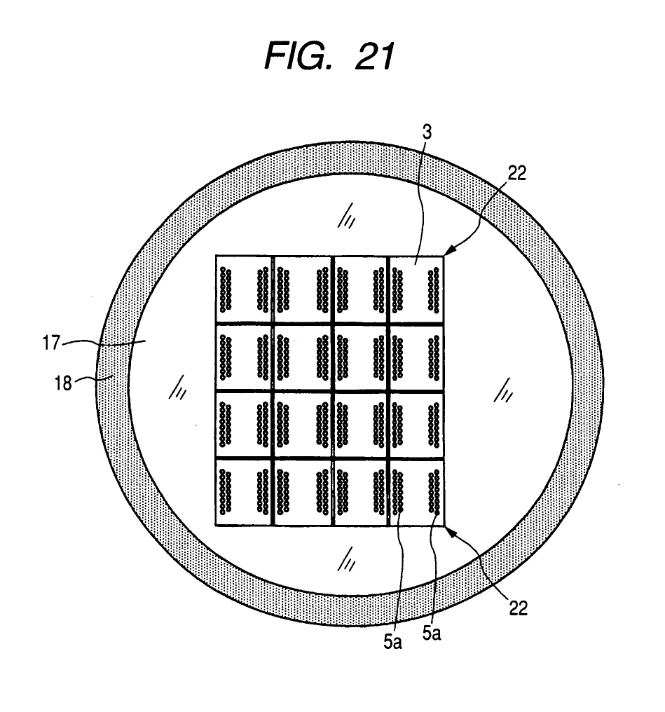

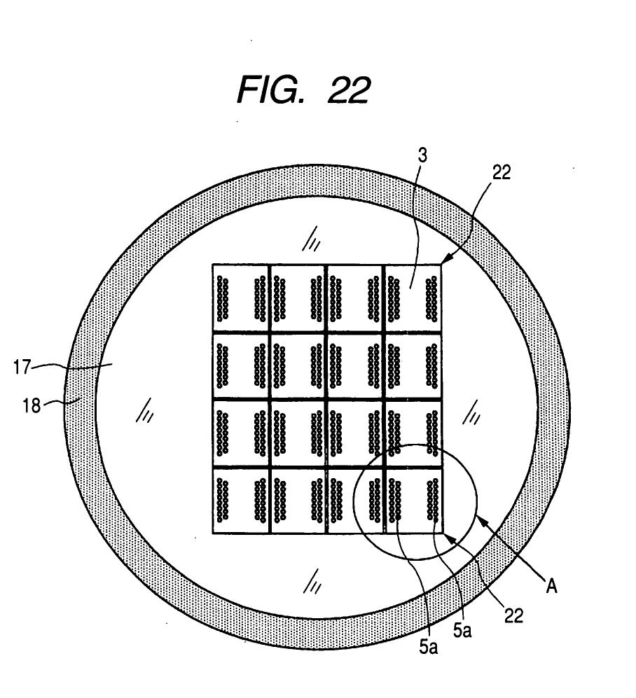

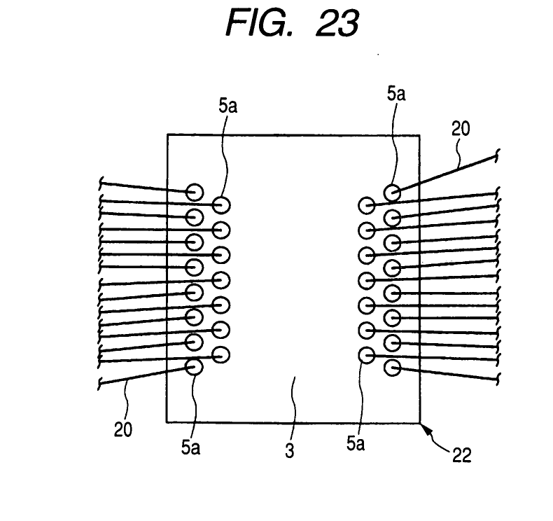

FIG. 15 is a plan view showing an example of the internal structure of a semiconductor device according to an embodiment 2 of the present invention in a state that the inner structure is viewed through the sealing body in a see-through manner, FIG. 16 is a cross-sectional view showing the structure of a cross section taken along a line A-A shown in FIG. 15, FIG. 17 is a plan view showing the structure of the semiconductor device shown in FIG. 15, FIG. 18 is a back view showing the structure of the semiconductor device shown in FIG. 15, FIG. 19 is a back view showing the internal structure of a back side of a chip of the semiconductor device shown in FIG. 15, FIG. 20 is a plan view showing an example of the structure when a dicing tape is adhered in an assembling step of the semiconductor device shown in FIG. 15, FIG. 21 is a plan view showing an example of the structure after a sealing body is cut into individual pieces in the assembling step of the semiconductor device shown in FIG. 15, FIG. 22 is a plan view showing an example of the structure when the selection is performed in the assembling step of the semiconductor device shown in FIG. 15, and FIG. 23 is a partial plan view showing an example of the structure of a portion A shown in FIG. 22.

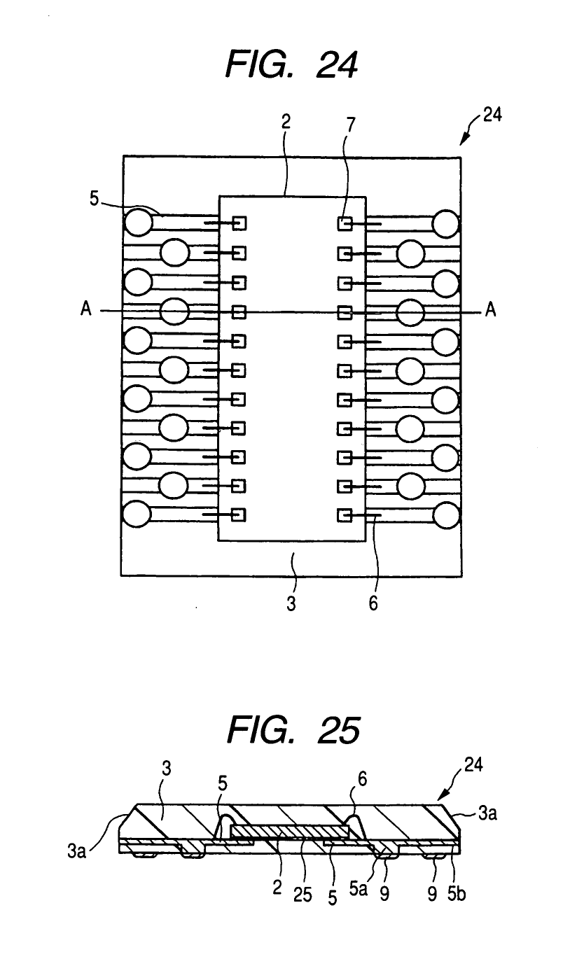

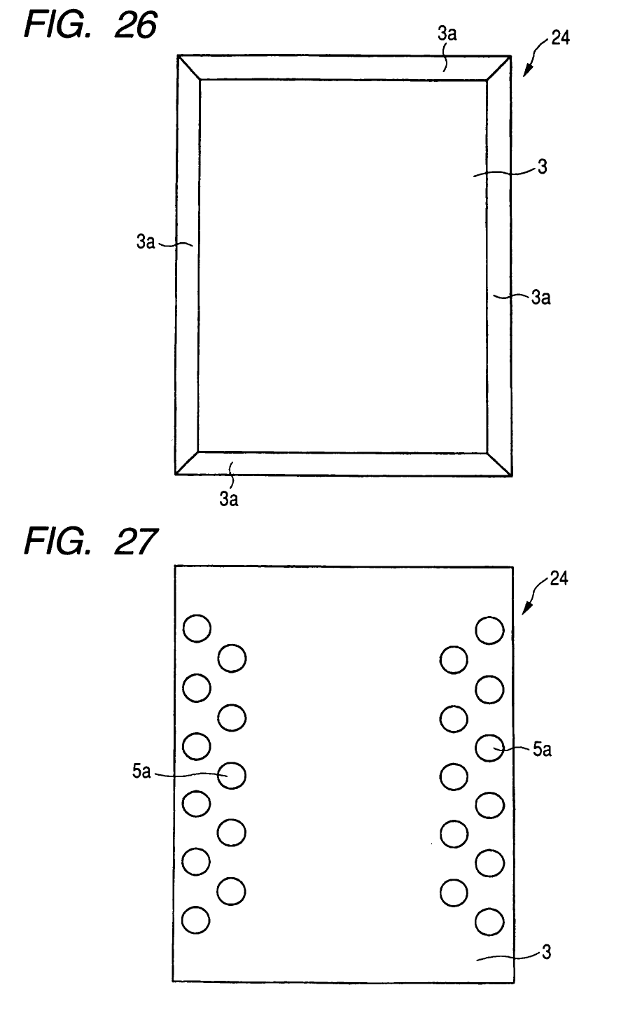

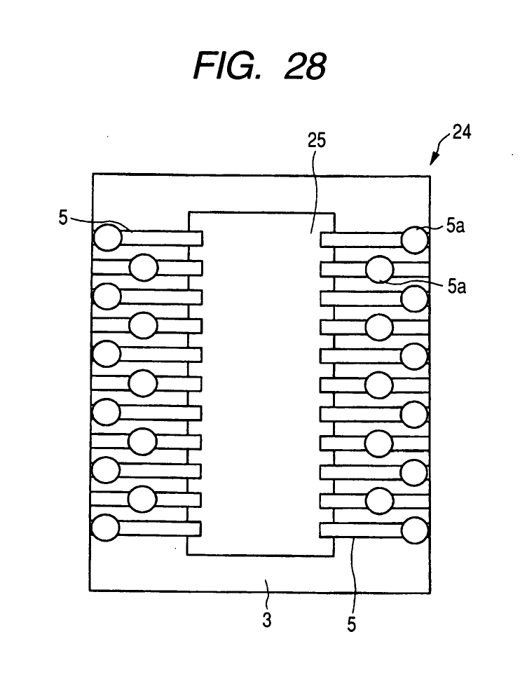

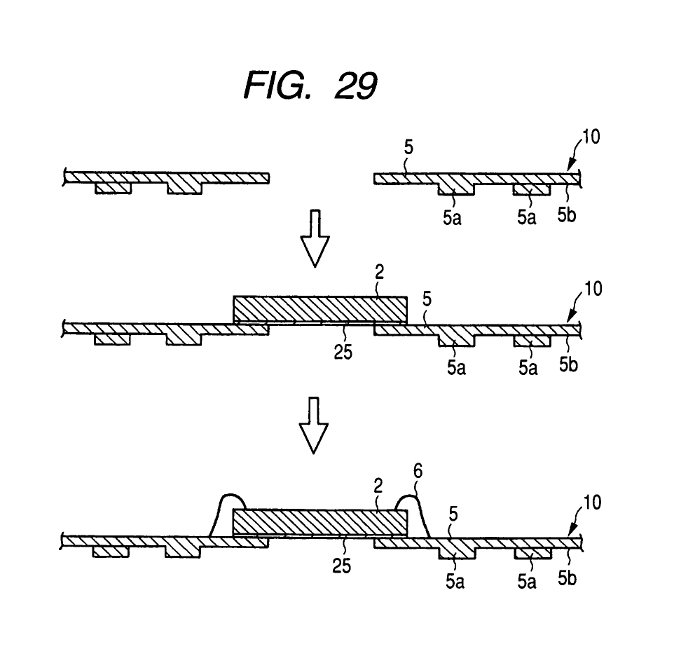

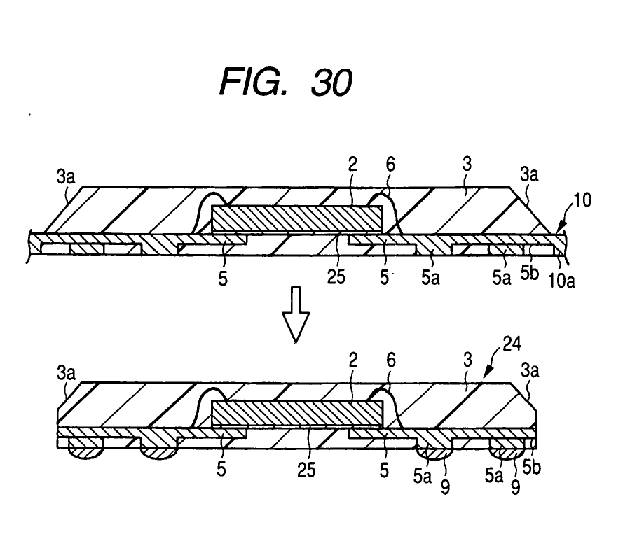

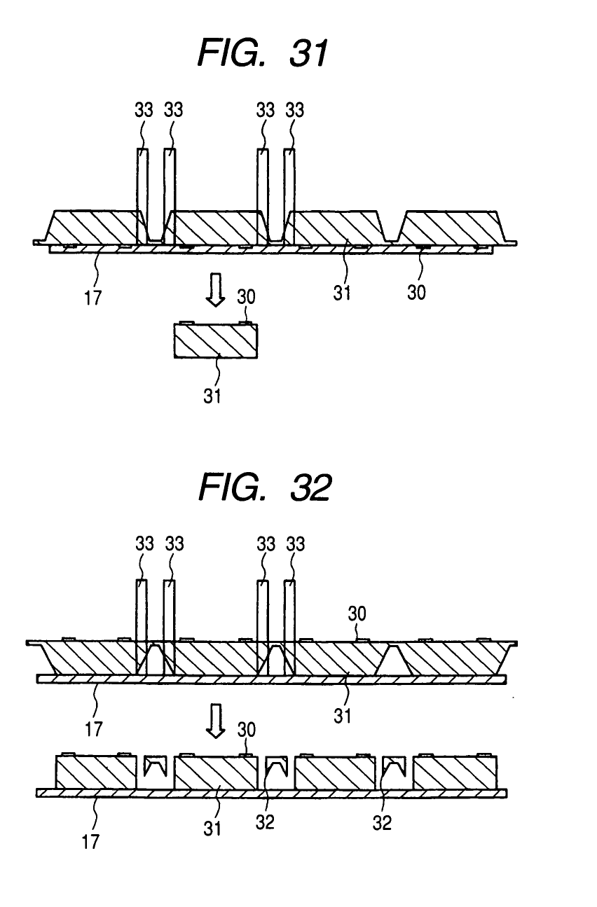

Here, FIG. 24 is a plan view showing the internal structure of a semiconductor device which is a modification of an embodiment 2 of the present invention in a state that the inner structure is viewed through the sealing body in a see-through manner, FIG. 25 is a cross-sectional view showing the structure of a cross section taken along a line A-A shown in FIG. 24, FIG. 26 is a plan view showing the structure of the semiconductor device shown in FIG. 24, and FIG. 27 is a back view showing the structure of the semiconductor device shown in FIG. 24. Further, FIG. 28 is a back view showing the internal structure of a back side of a chip of the semiconductor device shown in FIG. 24, FIG. 29 is a partial cross-sectional view showing the structure up to wire bonding which is the assembling step of the semiconductor device of a modification shown in FIG. 24, and FIG. 30 is a partial cross-sectional view showing the structure after resin molding which is the assembling step of the semiconductor device of a modification shown in FIG. 24.

The semiconductor device of the embodiment 2 shown in FIG. 15 to FIG. 19 is, in the same manner as the QFN 1 of the embodiment 1, a resin-sealed type and a surface-mounting type small semiconductor package. However, as shown in FIG. 18, the semiconductor device has such a constitution that, on a back surface of the sealing body 3 which is formed into quadrangular shape, external terminals (portions) 5a of the plurality of leads 5 are exposed along two opposing sides out of four sides of a peripheral portion of the back surface.

In the embodiment 2, the semiconductor device is explained by taking an SON 22 as an example. In the SON 22, the plurality of external terminal 5a which is arranged along the respective opposing sides in the back surface of the sealing body 3 is arranged in two rows in a staggered manner thus increasing pins. Further, the semiconductor chip 2 is mounted on a tub 4 having an area smaller than an area of the semiconductor chip 2 by way of an Ag paste 14 or the like, and a bonding pad 7 of the semiconductor chip 2 and an end portion of the lead 5 corresponding to the bonding pad 7 are electrically connected to each other using an Au wire 6. Although the semiconductor chip 2 which is mounted on the SON 22 mainly includes a memory circuit, it is not limited to such an semiconductor chip 2.

Also in assembling the SON 22, after resin molding, as shown in FIG. 20, the dicing tape 17 which is held by a tape fixing jig 18 may be adhered to the surface side of the sealing body 3 while directing back surfaces of the plurality of the sealing body 3 upwardly.

Thereafter, the package dicing is performed as shown in FIG. 21. That is, in the same manner as the package dicing of the QFN 1 of the embodiment 1, while adhering the dicing tape 17 to the surfaces of the plurality of sealing bodies 3, blade 19 for dicing (see FIG. 13) are allowed to intrude into the sealing bodies 3 from the back surface side (above) of the sealing bodies 3 and, thereafter, the leads 5 are cut along dicing lines 23 shown in FIG. 20 together with the inclined portions 3a of the sealing bodies 3.

Here, in the same manner as the package dicing of the embodiment 1, the inclined portion 3a of the side surface of the sealing body 3 and a thin wall portion 5b of the lead 5 are cut by performing only one-time dicing using the blade 19 having a large width thus performing the package dicing.

After completion of the package dicing, as shown in FIG. 22 and FIG. 23, a state in which a plurality of cut sealing bodies 3 is fixed to the dicing tape 17 is maintained and, in the above-mentioned state, probes 20 are brought into contact with the external terminals 5a which are arranged on the back surfaces of the sealing bodies 3 directed upwardly thus performing a test for selection.

That is, the test is performed by bringing the probes 20 into contact with the external terminals 5a thus selecting the SON 22 having good quality.

Accordingly, also in the manufacturing method of the semiconductor device of the embodiment 2, in the same manner as the embodiment 1, the package dicing is performed in a state that the dicing tape 17 is adhered to the surface of the plurality of the sealing bodies 3 and, thereafter, a selecting test is performed in a state that the plurality of sealing bodies 3 is fixed to the dicing tape 17. Accordingly, after package dicing, the test can be performed while holding the sealing bodies 3 by the dicing tape 17 without accommodating the sealing bodies 3 into the tray.

Accordingly, in assembling the SON 22, the processing efficiency can be enhanced.

Here, other advantageous effects which are obtained by the manufacturing method of the semiconductor device of the embodiment 2 are substantially equal to those of the embodiment 1 and hence, the repeated explanation is omitted.

The semiconductor device shown in FIG. 24 to FIG. 28 exhibits the structure of a SON 24 which is a modification of the embodiment 2. Here, although the SON 24 has the same basic structure as the SON 22, the SON 24 adopts the structure in which the semiconductor chip 2 is mounted on a chip-side end portion (one end) of each lead 5.

Accordingly, the semiconductor chips 2 are mounted on the chip-side end portions (one ends) of the plurality of respective leads 5 by way of an insulative tape material (insulative adhesive material) 25.

Also in assembling the SON 24, as shown in FIG. 29 and FIG. 30, after performing the die bonding, the wire bonding and the resin molding, in the same manner as the QFN 1 of the embodiment 1, the inclined portion 3a of the side surface of the sealing body 3 and the thin-wall portion 5b of the lead 5 are cut by performing dicing only one time using the blade 19 (see FIG. 13) having a large width thus completing the package dicing. Further, after completion of the package dicing, the state in which the plurality of sealing bodies 3 is fixed to the dicing tape 17 (see FIG. 20) is maintained and, in the above-mentioned state, the probes 20 are brought into contact with the external terminals 5a which are arranged on the back surfaces of the sealing bodies 3 directed upwardly thus performing the test for selection.

Accordingly, also in the case of the SON 24 of the modification, after package dicing, the test can be performed while holding the sealing bodies 3 by the dicing tape 17 without accommodating the sealing bodies 3 into the tray. As a result, in assembling the SON 24, the processing efficiency can be enhanced.

Although the invention made by the inventors of the present invention has been specifically explained in conjunction with the embodiments heretofore, it is needless to say that the present invention is not limited to the above-mentioned embodiments and various modifications are conceivable without departing from the gist of the present invention.

For example, in the embodiment 1, although a case in which the blade 19 having a large width has a thickness (width) of 1 mm has been explained as an example, the blade 19 may have a thickness other than 1 mm so long as the blade 19 can cut the inclined portion 3a of the side surface of the sealing body 3 and the thin-wall portion 5b of the lead 5 by performing only one time dicing.

The present invention is applicable to an assembling of a semiconductor device which performs a resin molding by a through-gate method.

What is claimed is:

1. A manufacturing method of a semiconductor device comprising the steps of:
(a) preparing a lead frame, the lead frame including tabs constituting chip mounting portions and a plurality of leads arranged around the tabs;
(b) mounting semiconductor chips over the tabs;
(c) electrically connecting the semiconductor chips and the plurality of leads with each other by conductive wires;
(d) forming a plurality of sealing bodies by sandwiching the lead frame by an upper mold and a lower mold which constitute resin forming molds, and by supplying a sealing resin into the inside of a plurality of cavities which are formed between the upper mold and the lower mold and are connected with each other through communication gates;
(e) cutting, after the step (d), portions of the leads and the sealing bodies of the lead frame by adhering a dicing tape to surfaces of the plurality of sealing bodies and by allowing blades for dicing to intrude into the sealing bodies from back surface sides of the sealing bodies in a dicing-tape adhered state; and
(f) performing, after the step (e), a test by bringing probes into contact with external terminals which are arranged over back surfaces of the sealing bodies in a state that front surfaces of the plurality of cut sealing bodies are fixed to the dicing tape.

2. A manufacturing method of a semiconductor device according to claim 1, wherein in the step (e), at inclined portions of respective side surfaces of the plurality of sealing bodies, the portions of the leads and the sealing bodies are cut by the blades.

3. A manufacturing method of a semiconductor device according to claim 1, wherein the lead has a first portion which is exposed on the back surface of the sealing body and a second portion which is embedded in the inside of the sealing body and, in the step (e), at the respective second portions of the plurality of leads, the portions of the leads and the sealing bodies are cut by the blades.

4. A manufacturing method of a semiconductor device according to claim 3, wherein the second portion of the lead is made thinner than the first portion by half etching.

5. A manufacturing method of a semiconductor device according to claim 1, wherein the lead has a first portion which is exposed on the back surface of the sealing body and a second portion which is embedded in the inside of the sealing body, and the blade used in the step (e) is formed with a thickness which allows edge portions thereof arranged at the inclined portion of the side surface of the sealing body and at the second portion of the lead.

6. A manufacturing method of a semiconductor device according to claim 1, wherein the lead has a first portion which is exposed on the back surface of the sealing body and a second portion which is formed thinner than the first portion and, in the step (e), the portions of the leads and the sealing bodies are cut by the blades at the respective second portions of the plurality of leads.

7. A manufacturing method of a semiconductor device according to claim 1, wherein, in the step (e), the portions of the leads and the sealing bodies are cut by the blades having a width of 1 mm.

8. A manufacturing method of a semiconductor device according to claim 1, wherein in the step (e), the portions of the leads and the sealing bodies are cut by the blades in a state that the blades are spaced apart from the dicing tape.

9. A manufacturing method of a semiconductor device according to claim 1, wherein in the step (f), the tests of the plurality of semiconductor devices are simultaneously performed by bringing the probes into contact with external terminals of the plurality of semiconductor devices over the dicing tape.

10. A manufacturing method of a semiconductor device according to claim 1, wherein the back surface of the sealing body is formed to have a quadrangular shape, and portions of the plurality of leads are exposed along four respective sides of a peripheral portion of the back surface.

11. A manufacturing method of a semiconductor device according to claim 1, wherein the back surface of the sealing body is formed to have a quadrangular shape, and the portions of the plurality of leads are exposed along two opposing sides out of four sides of a peripheral portion of the back surface.

12. A manufacturing method of a semiconductor device which includes a plurality of leads, semiconductor chips which are mounted on respective one ends of the plurality of leads, a plurality of conductive wires which electrically connect the semiconductor chips and the plurality of leads, and a sealing body which seals the plurality of leads, the plurality of semiconductor chips and the plurality of conductive wires with a resin, wherein the respective portions of the plurality of leads are exposed on a back surface of the sealing body,
the manufacturing method of a semiconductor device comprising the steps of:
(a) preparing a lead frame which includes the plurality of leads;
(b) mounting the semiconductor chips on the respective one ends of the plurality of leads by way of an insulating adhesive material;
(c) electrically connecting the semiconductor chips and the plurality of leads with each other by the conductive wires;
(d) forming a plurality of sealing bodies by sandwiching the lead frame by an upper mold and a lower mold which constitutes resin forming molds, and by supplying a sealing resin into the inside of a plurality of cavities which are formed between the upper mold and the lower mold and are connected with each other through communication gates;
(e) cutting, after the step (d), portions of the leads and the sealing bodies of the lead frame by adhering a dicing tape to surfaces of the plurality of sealing bodies and by allowing blades for dicing to intrude into the sealing bodies from back surface sides of the sealing bodies in a dicing-tape adhered state; and
(f) performing, after the step (e), a test by bringing probes into contact with external terminals which are arrange over back surfaces of the sealing bodies in a state that the plurality of cut sealing bodies are fixed to the dicing tape.

13. A manufacturing method of a semiconductor device according to claim 12, wherein in the step (e), at inclined portions of respective side surfaces of the plurality of sealing bodies, the portions of the leads and the sealing bodies are cut by the blades.

14. A manufacturing method of a semiconductor device according to claim 12, wherein the lead has a first portion which is exposed on the back surface of the sealing body and a second portion which is embedded in the inside of the sealing body and, in the step (e), at the respective second portions of the plurality of leads, the portions of the leads and the sealing bodies are cut by the blades.

15. A manufacturing method of a semiconductor device according to claim 12, wherein the lead has a first portion which is exposed on the back surface of the sealing body and a second portion which is embedded in the inside of the sealing body, and the blade used in the step (e) is formed with a thickness which allows edge portions thereof to be arranged at the inclined portion of the side surface of the sealing body and at the second portion of the lead.

16. A manufacturing method of a semiconductor device according to claim 12, wherein in the step (e), the portions of the leads and the sealing bodies are cut by the blades in a state that the blades are spaced apart from the dicing tape.

17. A manufacturing method of a semiconductor device according to claim 12, wherein in the step (f), the tests of the plurality of the semiconductor devices are simultaneously performed by bringing the probes into contact with external terminals of the plurality of semiconductor devices over the dicing tape.
